(19) United States
(12) Patent Application Publication
(10) Pub. No.: US 2016/0112041 A1
(43) Pub. Date: Apr. 21, 2016

(54) POWER TRANSISTOR MODEL

(71) Applicant: Infineon Technologies Austria AG, Villach (AT)

(72) Inventors: Kevni Bueyuektas, Muenchen (DE); Uwe Wahl, Muenchen (DE); Andreas Schloegl, Ottobrunn (DE); Gerhard Noebauer, Villach (AT)

(21) Appl. No.: 14/514,476

(22) Filed: Oct. 15, 2014

(51) Int. Cl. H03K 17/687

(52) U.S. Cl. CPC H03K 17/687

(57) ABSTRACT

A power transistor model is described which comprises a source drain path, a first current source and a voltage controlled second current source in the source drain path which model the static voltage-current-relationship of a modeled power transistor, wherein the voltage-controlled second current source models a nonlinear behavior of a drift zone of the power transistor.

### TECHNICAL FIELD

The present disclosure relates to power transistor models.

### BACKGROUND

For the design of a complex electronic circuit a simulation is typically performed for verifying the functionality of the electronic circuit and for optimizing its performance For such simulations, accurate models for the components used in the circuit are desirable. In particular, accurate models for power transistors which can be used with low effort are desirable.

### SUMMARY

According to one embodiment, a power transistor model is provided which includes a source drain path, a first current source and a voltage controlled second current source in the source drain path which model the static voltage-current-relationship of a modeled power transistor, wherein the voltage-controlled second current source models a nonlinear behavior of a drift zone of the power transistor.

According to a further embodiment, a power transistor model is provided including a gate terminal, a source terminal and a drain terminal and a capacitance network including one or more nonlinear voltage dependent capacitances, wherein each nonlinear voltage dependent capacitance is connected between the drain terminal and the source terminal or the drain terminal and the gate terminal.

Further, according to one embodiment, a method for simulating the behavior of an electronic circuit including a power transistor using one or a combination of the power transistor models as described above is provided.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various aspects are described with reference to the following drawings, in which:

FIG. 1 shows a typical equivalent circuit diagram for a power transistor including standard elements and standard transistors.

FIG. 2 shows a power transistor model according to an embodiment.

FIG. 3 shows a power transistor model according to a further embodiment.

FIG. 4 shows a transistor sub-circuit of a transistor model according to one embodiment.

FIG. 5 shows a capacitance network of the transistor model according to one embodiment.

FIG. 6 shows a package parasitic network of the transistor model according to one embodiment.

FIG. 7 shows an output characteristic of a transistor model according to an embodiment.

FIG. 8 shows an transfer characteristic of a transistor model according to an embodiment.

FIGS. 9 to 14 illustrate the nonlinearity of the drain-gate capacitance of a transistor model according to an embodiment.

FIGS. 15 to 18 illustrate the nonlinearity of the drain-source capacitance of a transistor model according to an embodiment.

### DESCRIPTION

The following detailed description refers to the accompanying drawings that show, by way of illustration, specific details and aspects of this disclosure in which the invention may be practiced. Other aspects may be utilized and structural, logical, and electrical changes may be made without departing from the scope of the invention. The various aspects of this disclosure are not necessarily mutually exclusive, as some aspects of this disclosure can be combined with one or more other aspects of this disclosure to form new aspects.

For the development of complex electronic circuits or systems the functionality is typically checked and optimized for the desired performance by means of circuit simulation. For such simulations, suitable component models are necessary which describe the behavior of the electrical components for the various operating points electrically (and possibly also thermically) with sufficient accuracy. To achieve the sufficient accuracy, there are model levels ranging from level 0 to level 3.

While the modeling of MOSFETs (metal-oxide-semiconductor field-effect-transistors) as component of integrated circuits has a long tradition (e.g. transistor models based on BSIM (Berkeley Short-channel IGFET Model) are widely used) the characteristics of power MOSFETs are typically modeled with low accuracy. For example, because of the structure of a power MOSFET including a high number of MOS cells for scaling the resistance with serially connected drift region for electric strength a BSIM based model is typically not suitable since BSIM has been optimized to address issues of large scale integration such as for example short channel effects (such as drain induced barrier lowering).

In particular the drift region which has a nonlinear effect for the drain current and is characteristic for a vertical power MOSFET is typically not modeled by compact models. Further, the parasitic capacities of power transistors such as Multi-Epi Super Junction MOS Transistors have a very characteristic behavior. Namely, due to the technological structure the capacity in dependency of the voltage may have sharp bends. Standardized compact models can typically not take this characteristic into account.

There are various approaches for describing the characteristics of power MOSFETs based on models.

A simple and fast way to verify the functionality of a transistor based on a computer is a simulation using compact models. There are a high number of analytical models developed mostly by companies, institutes and universities which typically also have the exclusive rights for them. The CMC (Compact Model Council) is an international working group which takes care of standardization, definition of simulator interfaces and the availability of compact models. Popular circuit simulation tools (like PSpice, ADS, Spectre etc.) in general have standardized transistor libraries. Compact models are typically considered to have the following benefits:
standardization and versioning of the models
general availability in various simulator environments
high reliability and stability (since they are thoroughly tested and evaluated by the CMC)
short simulation times
detailed descriptions and manuals

In the following, a comparison of popular compact models with respect to their applicability to power transistors e.g. SJ-MOSFETs (super junction MOSFETS) such as CoolMOS is given

a) Standard MOS level 1-3 (Level 1: Schichman-Hodges model, Level 2: Grove-Frohman model, Level 3: Empirical model)
modeling of the nonlinear drift zone is not taken into account
body diode is not implemented
input, output and miller capacitance are not considered

### b) BSIM (Berkeley Short-Channel IGFET Model)

modeling of the nonlinear drift zone is not taken into account
high complexity, high number of parameters (e.g. BSIM3v3 approx. 130)
capacity model is unsuitable for SJ-FET
many effects are considered which are unimportant for power MOS transistors such as channel length modulation etc.

### c) HiSIM

modeling of the nonlinear drift zone is not taken into account
high complexity, high number of parameters
physical model whose structure does not correspond to the SJ-MOSFET and is therefore inadequate
capacity model is unsuitable for SJ-FET

### d) HiSIM-HV

high complexity, high number of model parameters (e.g. approx. 300 for version 1.2.0)
capacity model is not sufficiently accurate for SJ-FET
only a lateral model is available. CoolMOS, for example, has a vertical topology
inconsistent behavior in different simulators

Another approach for modeling MOS transistors is the development of equivalent circuit diagrams This approach is typical of use when a compact model alone cannot sufficiently describe the electrical characteristics of the component (i.e. the transistor in this case) or when there are effects because of the technological structure which the models do not reflect.

For a SJ-MOSFET, there are for example the following typical characteristics:
the non-linearity of the current in the drain source path (drift zone) is caused by the constriction of the space charge regions around the p-columns This electrical behavior can be described as J-FET (junction FET) effect.
the body diode is uniquely defined by the technological structure of the SJ-MOSFET between the source columns (p-doted) and the substrate (n-doted). Since this diode function is not present in most compact models it needs to be externally added.
typical capacitance models do not properly reflect the behavior of parasitic capacitances which is affected by sharp bends and discontinuities.

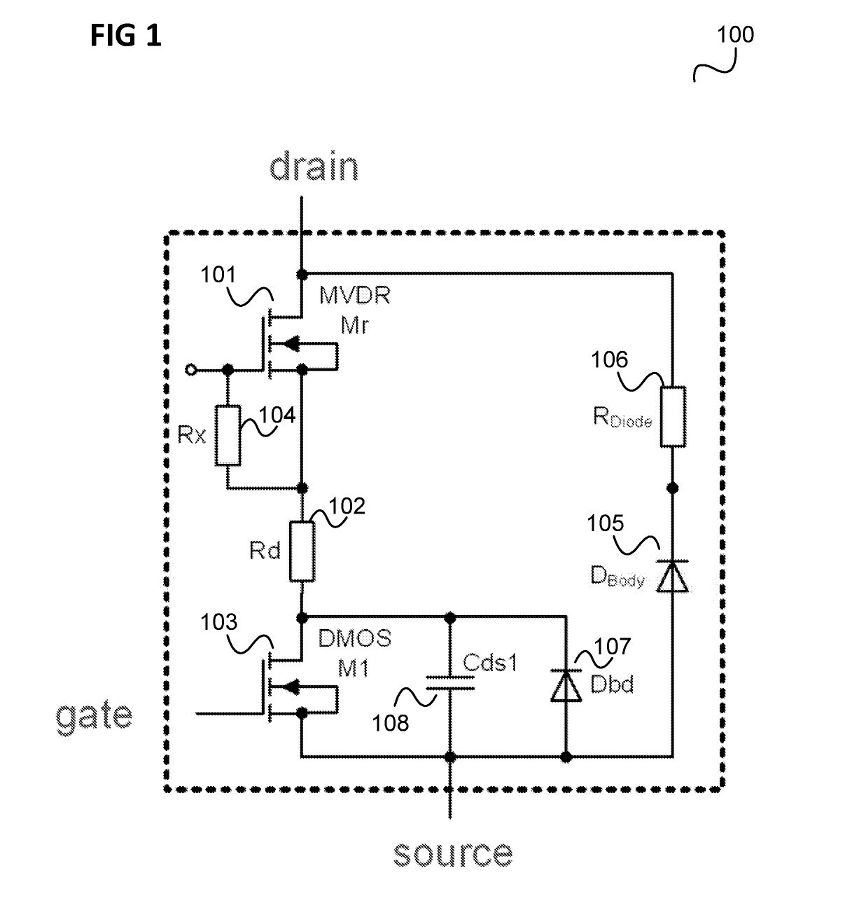

FIG. 1 shows a typical equivalent circuit diagram 100 for a power transistor including standard elements and standard transistors.

According to the equivalent circuit diagram 100, the power transistor includes a first n-channel field effect transistor 101 whose drain forms the power transistor's drain terminal and whose source is connected, via a first resistor 102, with a second n-channel field effect transistor 103 whose source forms the power transistor's source terminal and whose gate forms the power transistor's gate terminal.

The gate of the first n channel FET 101 is connected to its source via a second resistor 104. The power transistor's source is connected via a serial connection of a first diode 105 and a third resistor 106 to its drain. Further, its source is connected via a parallel connection of a second diode 107 and a capacitance 108 to the drain of the second n channel FET 103.

In the following, embodiments of power transistor models are described which allow an accurate and efficient modeling of power field effect transistors.

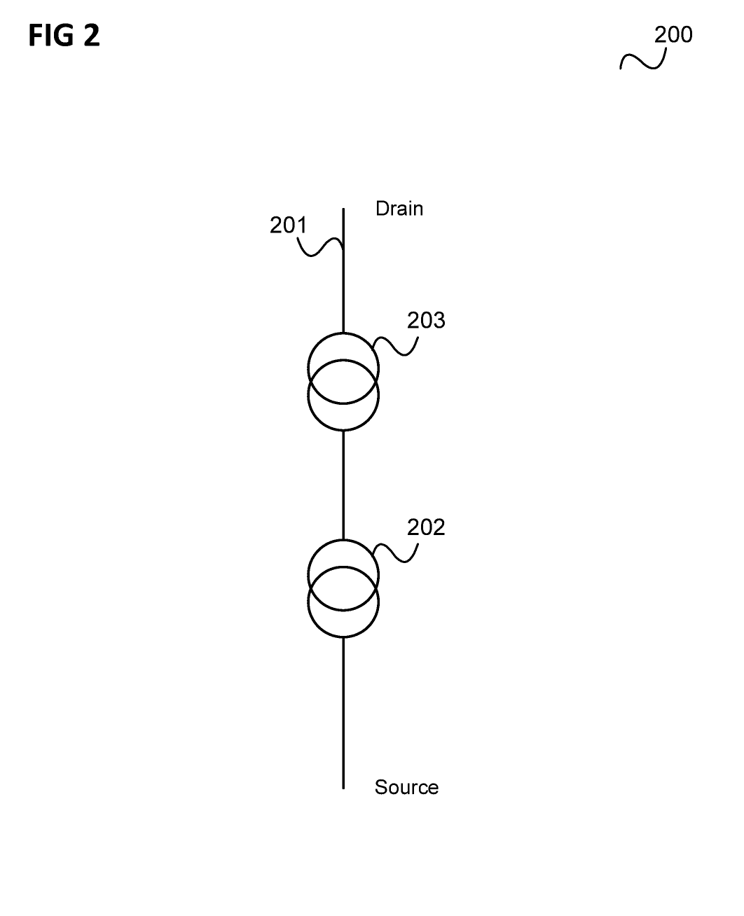

FIG. 2 shows a power transistor model 200 according to an embodiment.

The power transistor model 200 includes a source drain path 201, a first current source 202 and a voltage controlled second current source 203 in the source drain path which model the static voltage-current-relationship of a modeled power transistor.

The voltage-controlled second current source 202 models a nonlinear behavior of a drift zone of the power transistor.

According to one embodiment, in other words, a voltage controlled current source is included in a power transistor model which is controlled such that it reflects the behavior of the power transistor drift zone.

The voltage-controlled second current source for example models a JFET effect.

According to one embodiment, the second current source is voltage-controlled by the voltage over the second current source.

The second current source has for example the behavior of a non-linear resistor.

According to one embodiment, the second current source is connected in series to the first current source.

The first current source for example gives a channel current depending on the drain source voltage and depending on the gate source voltage of the power transistor.

The first current source may give a channel current depending on the size of the active area of the power transistor.

According to one embodiment, the power transistor model further includes a body diode model arranged in a path which is parallel to the part of the source drain path which includes the first current source.

The path is for example serial to the part of the source drain path which includes the second current source.

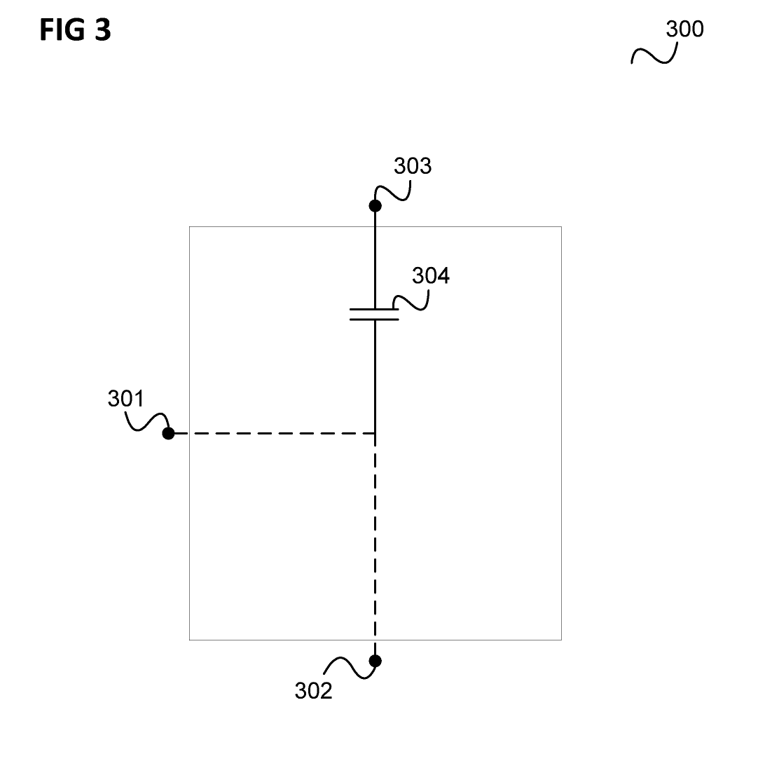

FIG. 3 shows a power transistor model 300 according to an embodiment.

The power transistor model 300 includes a gate terminal 301, a source terminal and 302 and a drain terminal 303.

The power transistor model 300 further includes a capacitance network including one or more nonlinear voltage dependent capacitances 304, wherein each nonlinear voltage dependent capacitance 304 is connected between the drain terminal and the source terminal or the drain terminal and the gate terminal.

According to one embodiment, in other words, a capacitance network including at least one nonlinear voltage dependent capacitance is included in a power transistor model.

According to one embodiment, the capacitance network further includes a capacitance connected between the drain terminal and the source terminal.

The capacitance connected between the drain terminal and the source terminal is for example a voltage independent capacitance.

According to one embodiment, the capacitance network further includes a capacitance connected between the gate terminal and the source terminal.

The capacitance connected between the gate terminal and the source terminal is for example a voltage independent capacitance.

According to one embodiment, each nonlinear voltage dependent capacitance is modeled by means of a voltage-controlled voltage source.

Each nonlinear voltage dependent capacitance is for example modeled by means of a serial connection of a voltage-controlled voltage source and a voltage-independent capacitance.

According to one embodiment, the capacitance network includes one or more nonlinear voltage dependent capacitances connected between the drain terminal and the source terminal and includes one or more nonlinear voltage dependent capacitances connected between the drain terminal and the gate terminal.

The capacitances for example model parasitic capacitances. The behavior of the parasitic capacitances is for example addressed by an individual, formula-based determination.

It should be noted that the features of the power transistor models according to FIG. 2 and FIG. 3 may be combined into one power transistor model (including any of the optional features).

According to one embodiment, the characteristic of a power transistor, e.g. a power MOSFET such as a Superjunction MOSFET like the CoolMOS are modeled (e.g. by a computer-implemented model). The model may for example be used in system or circuit design to take into account the characteristics of the modeled component with high accuracy. For example a method for simulating the behavior of an electronic circuit including a power transistor is performed using a power transistor model according to one or a combination of the above power transistor models.

According to one embodiment, one or both or a combination of the models is used in a computer-based method for modeling the particular non-linear characteristics, specifically of super junction components such as CoolMOS transistor. According to one embodiment, as will be described below, a model is used which includes an equivalent circuit diagram including a capacitance network with controlled voltage sources and which may be supplemented by a package model.

In the following, embodiments are described in more detail.

The transistor model described in the following, which is in the following example a model for a CoolMOS transistor, can be seen to be neither a compact model nor a pure equivalent circuit diagram based model but rather an advanced version of an equivalent circuit in which additional physical formulas are implemented (empirical model). These formulas are used to take care of the special behavior of the CoolMOS transistor. By this approach, the following three significant characteristics can be represented by the model:
static characteristic curves (transfer function, output characteristic and body diode)
in particular the non-linear behavior of the drift zone (in the output characteristic)
CV-characteristics of the gate drain capacity (Cgd), the gate source capacity (Cgs) and the drain source capacity (Cds).

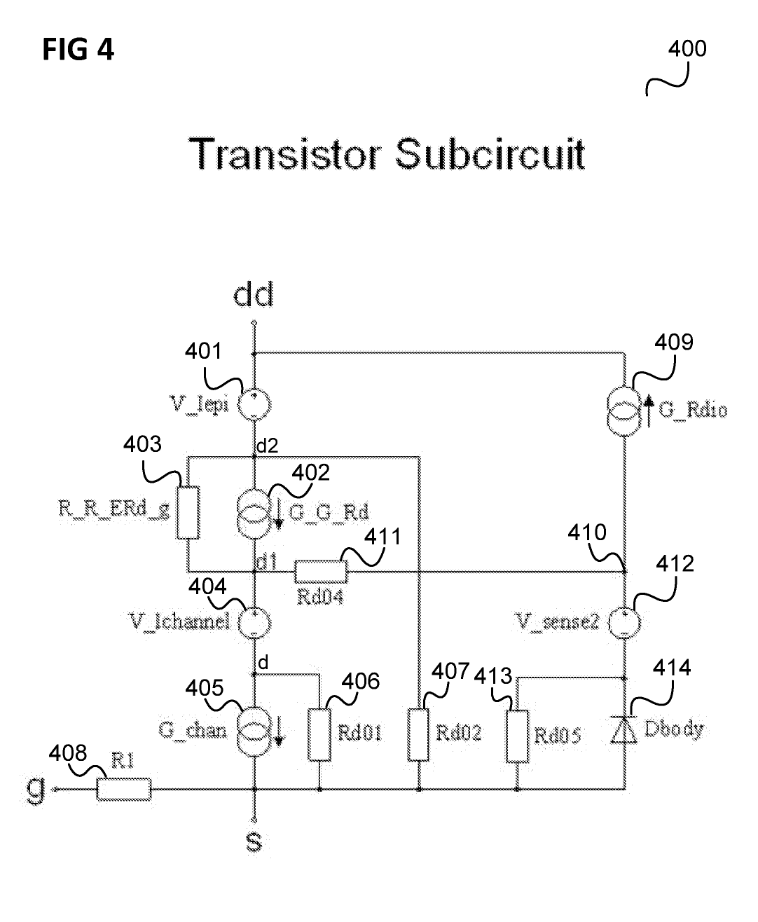

The transistor model is illustrated in three parts in FIGS. 4 to 6.

FIG. 4 shows a transistor sub-circuit 400 of a transistor model according to one embodiment.

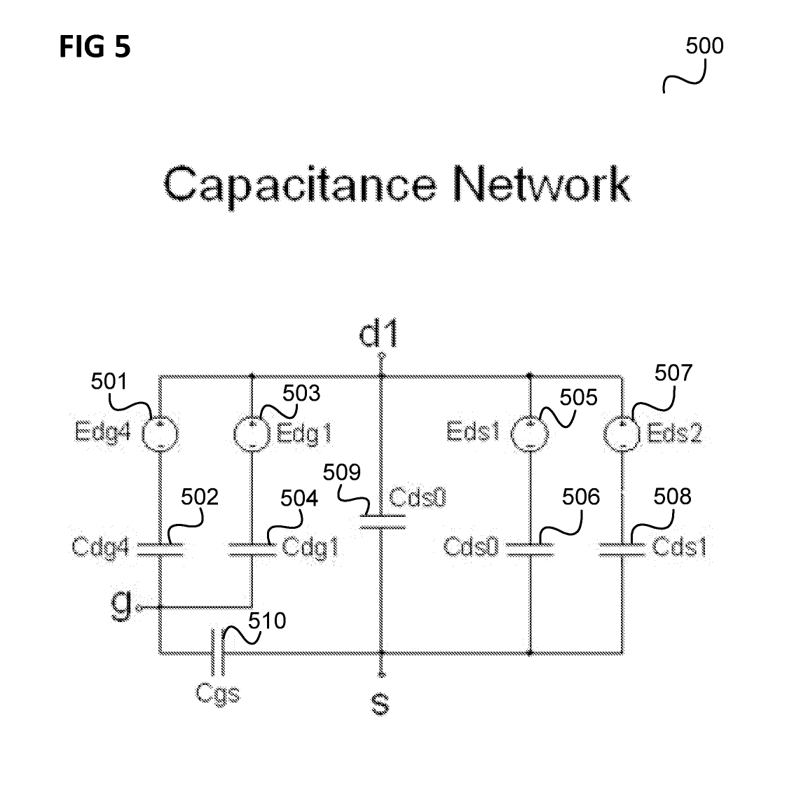

FIG. 5 shows a capacitance network 500 of the transistor model according to one embodiment.

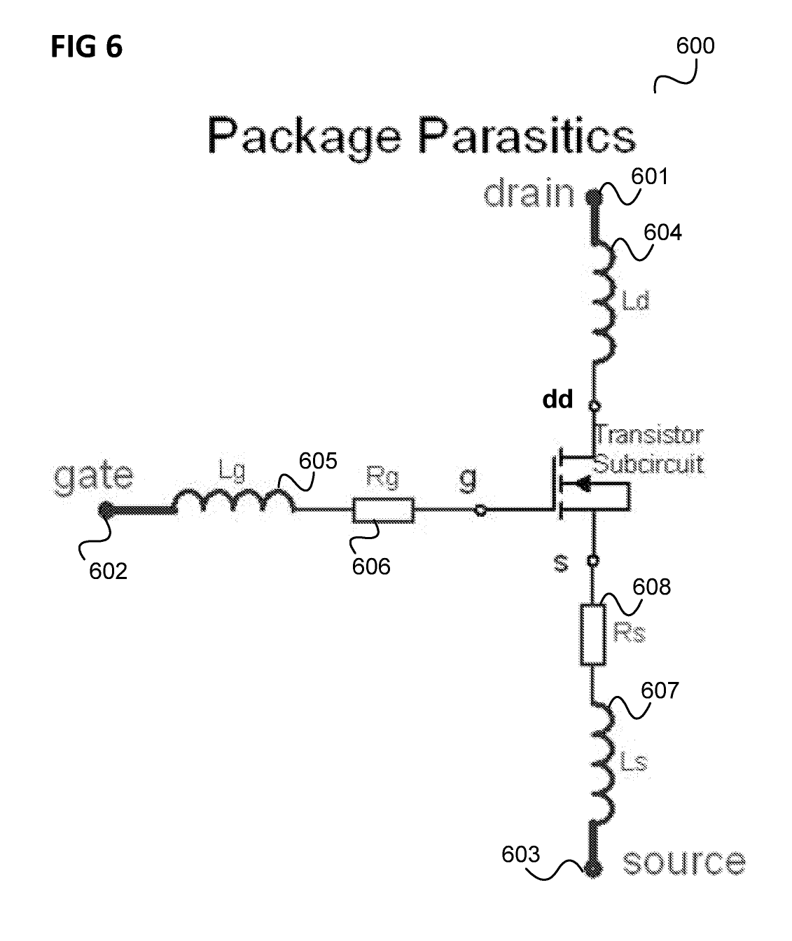

FIG. 6 shows a package parasitic network 600 of the transistor model according to one embodiment.

The transistor sub-circuit 400 and the capacitance network 500 each have a gate node g, a source node s and a node d1 via which they are connected.

The transistor sub-circuit 400 is connected to the package parasitic network 600 via the gate node g, the source node s and a drain node dd as illustrated in FIG. 6 such that the drain terminal 601, the gate terminal 602 and the source terminal 603 of the parasitic network 600 correspond to the drain terminal, the gate terminal and the source terminal of the modeled transistor.

The transistor sub-circuit 400 is characterized by the transistor technology and represents the current characteristics and voltage characteristics of the transistor. The capacity network 500 includes controlled voltage sources which model the non-linear behavior of the capacitances via voltage. The package parasitic network 600 is represented by inductances and resistances.

Specifically, the transistor sub-circuit 400 includes a first voltage source 401 (denoted as V_Iepi) between the drain node dd and a node d2. A first current source 402 (denoted as G_G_Rd) is connected between the nodes d1 and d2. The nodes d1 and d2 are further connected by means of a first resistor 403 (denoted as R_R_ERd_g). A second voltage source 404 (denoted as V_Ichannel) is arranged between node d1 and a node d. The node d is connected to the source node s by means of parallel connection of a second current source 405 (denoted as G_chan) and a second resistor 406 (denoted as Rd01). The node d2 is connected to the source node s by means of a third resistor 407 (denoted as Rd02).

The gate node g and the source node s are connected by means of a fourth resistor 408 (denoted as R1). A third current source 409 (denoted as G_Rdio) is connected between the drain node dd and a further node 410 which is connected to the node d1 by means of a fifth resistor 411 (denoted as Rd04). The further node 410 is further connected to the source node s by means of a third voltage source 412 (denoted as V_sense2) and the parallel connection of a sixth resistor 413 (denoted as Rd06) and a diode 414 (denoted as Dbody) whose anode is connected to the source node s.

The capacitance network 500 includes a first voltage source 501 (denoted as Edg4), connected in series with a first capacitance 502 (denoted as Cdg4) between the node d1 and the gate node g. The first voltage source 501 and the first capacitance 502 form a voltage-dependent capacitance.

Further, the capacitance network 500 includes a second voltage source 503 (denoted as Edg1), connected in series with a second capacitance 504 (denoted as Cdg1) between the node d1 and the gate node g. The second voltage source 503 and the second capacitance 504 form a voltage-dependent capacitance.

The capacitance network 500 further includes a third voltage source 505 (denoted as Eds1), connected in series with a third capacitance 506 (denoted as Cds0) between the node d1 and the source node s. The third voltage source 505 and the third capacitance 506 form a voltage-dependent capacitance.

The capacitance network 500 further includes a fourth voltage source 507 (denoted as Eds2), connected in series with a fourth capacitance 508 (denoted as CdS1) between the node d1 and the source node s. The fourth voltage source 507 and the fourth capacitance 508 form a voltage-dependent capacitance.

Additionally, the node d1 and the source node s are connected by a fifth capacitance 509 (denoted as Cds0) and the gate node g and the source node s are connected by a sixth capacitance 510 (denoted as Cgs).

The package parasitic network includes a first inductance 604 (denoted as Ld) connecting the drain node dd to the drain terminal 601. Further, a second inductance 605 (denoted as Lg) connects the gate terminal 602 via a first resistor 606 (denoted as Rg) with the gate node g. Further, a third inductance 607 (denoted as Ls) connects the source terminal 603 via a second resistor 608 (denoted as Rs) with the source node s.

The model as represented by the equivalent circuit diagram including the parts 400, 500, 600 allows an accurate simulation of a CoolMOS transistor in terms of
the nonlinear drain current
the nonlinear capacitances
the package parasitic
the thermal behavior.

The equivalent circuit diagram can be implemented in any simulation language (e.g. Spice, Spectre, Titan etc.) in form of code and/or a netlist and can then be simulated.

The transistor model can be seen to have the following significant characteristics:
a) consistent and valid for all technology platforms
b) scales with area
c) non-linearity of drain current
d) consideration of thermal behavior
e) non-linear capacitances

The model may be implemented in advanced design environments such as Cadence, ADS or Simplorer to make use of the features of these environments for the modeling such as
simultaneous adjustment of the model parameters for a plurality of transistors of a technology family (scaling)
testing and adjusting by means of a uniform test bench environment and modeling methodology (for accuracy and avoiding errors)
tuning and optimization (for speed, accuracy and automation)
system analysis

This allows a fast, cost efficient and accurate adjustment of the model, e.g. to a given transistor. It should be noted that a compact model may also allow using the tuning and optimization features of an advanced design environment but only relatively low speed could be achieved.

In the following, a formulation of the transistor model illustrated in FIGS. 4, 5 and 6 in PSpice code is given. The model includes a part describing the technology and a part including the package parameters and the thermal network. Comments are indicated with a ‘*’. The denotations used in FIGS. 4, 5 and 6 are used for the various components.

**********************************************************************
.SUBCKT cool_C7_HB dd g s Tj t1 PARAMS: a=1 dVth=0 dR=0 dgfs=0 Inn=1 Unn=1
Rmax=1
+gmin=1 Rs=1 Rp=1 dC=0 heat=0
*a: active area [mm\hat{ }2], Inn [A]/Unn [V]: drain current/voltage for Rmax definition*
*Rmax: Rdson max. [Ohm], Rs: source resistance [Ohm], Rp: drain resitance package,
gmin: min. conductance [S]*
*dVth: Vth0 sweep, dR: Rd sweep, dgfs: conductance sweep, dC: capacitance sweep,
heat: switch for heating*

| | | |
|---|---|---|
| .PARAM | dCmax=0.33 | dC1={1+dCmax*limit(dC,0,1)} |

*Fm: short-channel effect Vth(Vds)*

| | |
|---|---|
| .PARAM | Fm=0.0 |

*kbq: {kB/e}= Boltzmann constant x electron charge *

| | |
|---|---|
| .PARAM | kbq=85.8u |

*Tref: reference temp.[K], T0: 0-degree temperature [K]*

| | |
|---|---|
| .PARAM | Tref=298 T0=273 |

*c: smoothing coeff. for modeling transition from linear to saturation regime *

| | |
|---|---|
| .PARAM | c=1.154 |

*al: alpha, smoothing for Vds, empirical for JFET effect [1/V]*

| | |
|---|---|
| .PARAM | al=1.1 |

*UT: slope of breakthrough curve [V]*

| | |
|---|---|
| .PARAM | UT=0.3 |

* lB: current factor for breakthrough [A]*

| | |
|---|---|
| .PARAM | lB=−23 |

* UB: breakdown voltage [V], temp. coeff. for UB [V/K]*

| | |
|---|---|
| .PARAM | UB=715 ab=0.715 |

**** THRESHOLD VOLTAGE ****
*threshold voltage: Vth0: nominal [V], Vmin: minimal {V], Vmax: maximal [V]; auth:
temp. coeff. Vth0 [V/K]*

| | |
|---|---|
| .PARAM | Vth0=4.1 Vmin=3.4 Vmax=5.4auth=4.7m |
| .PARAM | Vth={Vth0+(Vmax−Vth0)*limit(dVth,0,1)−(Vmin−Vth0)*limit(dVth,−1,0)} |

**** EPI/JFET - PARAMETERS ****
*Uctemp: JFET temp. coeff. [1/K]*

| | |
|---|---|
| .PARAM | Uctemp=−2.4m |

*Uc: value at which the epi resistance is twice normal, JFET effect [V]*

| | |
|---|---|
| .PARAM | Uc=8.9 |

*Rd: drain resitance [Ohm], nmu: temp. coeff. for the dRd (temp. depend. part of drain
resitance)*

| | |
|---|---|
| .PARAM | Rd=0.83 nmu=3.0 |

*Rf: part of drain resistance (%) which is not temp. dependent*

| | |
|---|---|
| .PARAM | Rf=0.3 |

*nmu3: drain current temp. coeff.*

| | |
|---|---|
| .PARAM | nmu3=385m |

*B0: wcm/l [A/(mm\hat{ }2*V\hat{ }2)), slope of the channel*

| | |
|---|---|
| .PARAM | b0=3.45 r0={b0*((T0/Tref)**nmu3)*a} |
| .PARAM | r1={(Unn−Inn*Rs−Vth0)*r0} |
| .PARAM | r2={(Fm*SQRT(0.4)−c)*Inn*r0} |
| .PARAM | Rlim={(r1+2*r2*Rmax−SQRT(r1**2+4*r2))/(2*r2)} |

*dRd: total drain resistace inc. all effects [Ohm/mm\hat{ }2]

| | |
|---|---|
| .PARAM | dRd={Rd/a+if(dVth==0,limit(dR,0,1)*max(Rlim−Rd/a−Rs−Rp,0),0)} |

**** CHANNEL - PARAMETERS ****
*p0: subthreshold slope[V], p1: subthreshold temp. linear coeff. [1/K], p2 - subthr. temp.
\hat{ }2 coeff.[1/K\hat{ }2]*

| | |
|---|---|
| .PARAM | p0=4 p1=0 p2=0 |
| .PARAM | bm={c/((1/gmin−Rs)**2*Inn*a*(T0/Tref)**nmu3)} |
| .PARAM | bet={b0+(b0−bm)*if(dR==0,if(dVth==0,limit(dgfs,−1,0),0),0)} |

**** CAPACITANCES - PARAMETERS ****
*Cdg parameters, N-not scaled, V-virtual (only in functions, not in sub-circuit)*

| | | |
|---|---|---|
| .PARAM | CdgN1=70p | Cdg1={CdgN1*a*dC1} |
| .PARAM | CdgN2=2.0p | Cdg2={CdgN2*a*dC1} |
| .PARAM | CdgVN1=1.2f | CdgV1={CdgVN1*a*dC1} |
| .PARAM | CdgVN4=7.0p | CdgVN5=0.4p |

| | |
|---|---|
| .PARAM | CdgVN2=60f CdgVN3=1.2p CdgV2={(CdgVN2*a+CdgVN3)*dC1} |

*Cds parameters*

| | | |
|---|---|---|
| .PARAM | CdsN0=2.0p | Cds0={CdsN0*a*dC1} |
| .PARAM | CdsN1=391p | Cds1={a*CdsN1*dC1} |

| | |
|---|---|
| .PARAM | CdsVN1=1.256n |
| .PARAM | CdsVN2=69p |

*Cgs parameters*

| | | |
|---|---|---|
| .PARAM | CgsN2=200p | CgsN1=195p Cgs0={(CgsN2+CgsN1*a)*dC1} |

**** VOLTAGE CONTROLLED VOLTAGE SOURCES FOR CAPACITANCES
NETWORK - PARAMETERS & FUNCTIONS ****
*Sources for Cdg*

| | |
|---|---|
| .PARAM | eedg=−0.556 |
| .PARAM | x0={(CdgVN4−CdgN2)/CdgVN5} x1={CdgVN4/CdgVN5} dx={x1−x0} |

pc22=80

| | |
|---|---|
| .FUNC | QCdg1(x) {Cdg2*min(x,x1+CdgV2*max(x−x1,0)+CdgV1/2*max(0, x− |

pc22)**2+(Cdg2−CdgV2)*((limit(x,x0,x1)−x0)**3/(dx*dx)*((limit(x,x0,x1)−x0)/(2*dx)−
1))}
* Sources for Cds*

| | | |
|---|---|---|
| .PARAM | Eds1=−6000 | Eds2=−320 Eds3=−200 eeds1=−0.1667eeds2=−6.25m |

eeds3=−0.05

| | |
|---|---|
| .PARAM | a0={(CdsVN1−CdsN1)/CdsVN2} a1={CdsVN1/CdsVN2} da={a1−a0} |

| | |
|---|---|
| .FUNC | QCds1(x) {Cds1*min(x,a1)+Cds1*((limit(x,a0,a1)− |

a0)**3/(da*da)*((limit(x,a0,a1)−a0)/(2*da)−1))}
**** DIODE PARAMETERS ****
*Rdi: parasitic resistance area scaled [Ohm]*

| | |
|---|---|
| .PARAM | Rdi=84.0mdRdi={Rdi/a} |

*lnIsj: log. saturation current [log[A]], ta: transient time [s], ndi: emission coefficient*

| | |
|---|---|
| .PARAM | lnIsj={−27.97*1} ta=2u ndi={1*1.09} |

*nmu2: temp. coeff. for the diode Rdi*

| | |
|---|---|
| .PARAM | nmu2=0.78 |

*diode capacitance*

| | | |
|---|---|---|
| .PARAM | Cdio0=1.226p | Cdio={Cdio0*a*dC1} |

**** CAPACITANCES & VOLTAGE CONTROLLED VOLTAGE SOURCES
NETWORK FOR TRANSISTOR ****

| | | |
|---|---|---|
| E_Edg1 | d1 | ox VALUE {if(V(d1,g)>0,V(d1,g)−(exp(eedg*max(V(d1,g),0))− |

1)/eedg,0)}

| | | | |
|---|---|---|---|
| C_Cdg1 | ox | g | {Cdg1} |

| | | |
|---|---|---|
| E_Edg2 | d1 | ox2 VALUE {V(d1,g)−QCdg1(V(d1,g))/Cdg2} |

| | | | |
|---|---|---|---|
| C_Cdg2 | ox2 | g | {Cdg2} |

| | | | |
|---|---|---|---|
| C_Cds0 | d1 | s | {Cds0} |

| | | |
|---|---|---|
| E_Eds1 | d1 | edep1 VALUE {if(V(d1,s)>0,V(d1,s)−Eds1*(exp(eeds1*max(V(d1,s),0))− |

1)−Eds2*(exp(eeds2*max(V(d1,s),0))−1)−Eds3*(exp(eeds3*max(V(d1,s),0))−1),0)}

| | | | |
|---|---|---|---|
| C_Cds1 | edep1 | s | {Cds0} |

| | | |
|---|---|---|
| E_Eds2 | d1 | edep2 VALUE {V(d1,s)−QCds1(V(d1,s))/Cds1} |

| | | | |
|---|---|---|---|
| C_Cds2 | edep2 | s | {Cds1} |

| | | | |
|---|---|---|---|
| C_Cgs | g | s | {Cgs0} |

**** TRANSITOR CORE: voltage controlled current sources & resitances ****
* Channel *
.FUNC I0(Uee,p,pp,z1,cc) {if(Uee>pp,(Uee−cc*z1)*z1,p*(pp−p)/cc*exp((Uee−pp)/p))}
.FUNC Ig(Uds,T,p,Uee,cc)
{bet*(T0/T)**nmu3*I0(Uee,p,min(2*p,p+cc*Uds),min(Uds,Uee/(2*cc)),cc)}
.FUNC J(d,g,T,da,s)
+ {a*(s*(Ig(da,T,(p0+(p1+p2*T)*T)*kbq*T,g−Vth+auth*(T−Tref),c)+1*exp(min(1B+(d−
UB−ab*(T−Tref))/UT,25))))}

| | | | |
|---|---|---|---|
| G_chan | d | s | VALUE={J(V(d,s),V(g,s),T0+limit(V(Tj),− |

200,499),(SQRT(1+4*al*abs(V(d,s)))−1)/2/al,sgn(V(d,s)))}
V_Ichannel d1 d 0
* Epi, JFET *
.FUNC Rd0(T) {(Rf*dRd+(1−Rf)*dRd*(T/Tref)**nmu)}
*JFET nonlinearity correction*
.FUNC CF(T,Iepi) {(Uc**2)/max(1,Uc**2−(Rd0(T)*Iepi)**limit(2+Uctemp*(T−
Tref),1.2,3))}

| | |
|---|---|
| V_Iepi | dd d2 0 |

| | |
|---|---|
| G_G_Rd | d2 d1 VALUE {V(d2,d1)/(Rd0(T0+LIMIT(V(t1),− |

200,999))*CF(T0+LIMIT(V(t1),−200,999),abs(I(V_Iepi))))}
R_R_ERd_g d2 d1 10k

| | | | |
|---|---|---|---|
| R1 | g | s | 1G |

| | | | |
|---|---|---|---|
| Rd01 | d | s | 500Meg |
| Rd02 | d2 | s | 500Meg |

**** BODY DIODE MODEL & NETWORK ****
Dbody s dio dbody
.model dbody D (BV={UB*10), CJO ={Cdio}, TT={ta}, IS ={a*exp(lnIsj)} m={1*0.3}
RS={dRdi/100} N={ndi} )

| | | | |
|---|---|---|---|
| G_Rdio | dio2 | dd | VALUE={V(dio2,dd)/(dRdi*((limit(V(Tj),− |

200,999)+T0)/Tref)**nmu2)}

| V_sense2 dio2 | | dio 0 |
|---|---|---|
| Rd04 | d1 | dio2 1k |

| | | | |
|---|---|---|---|
| Rd05 | dio | s | 500Meg |

**** THERMAL NETWORK ****
G_G_Ptot_channel 0 Tj VALUE {heat*LIMIT(V(d,s)*I(V_Ichannel),0,100k) }

| | |
|---|---|
| G_G_Ptot_Epi | 0 t1 VALUE |

{heat*(LIMIT(V(dd,d1)*I(V_Iepi),0,100k)+LIMIT(V(dd,s)*I(V_sense2),0,100k))}
.ENDS
**********************************************************************
.SUBCKT IP_C7_Hb_L1 drain gate source PARAMS: dVth=0 dRdson=0

| | | |
|---|---|---|
| .PARAM | Rs=0 | Rg=0 Ls=0 Ld=0 Lg=0 |

**Area like in TCAD simulations **

| | | |
|---|---|---|
| *.PARAM | act=5.26 | Inn=2.64 Unn=10 Rmax=205m |

**Area to get the same conduction losses in TCAD and PSpice simulations

| | | |
|---|---|---|
| .PARAM | act=4.45 | Inn=2.4 Unn=10 Rmax=230m |

**Area to get the same Ron

| | | |
|---|---|---|
| *.PARAM | act=4.96 | Inn=2.4 Unn=10 Rmax=230m |

X1 dd g s Tj Tj cool_C7_HB PARAMS: a={act} dVth={dVth} dR={dRdson}
Inn={Inn} Unn={Unn}

+Rmax={Rmax} Rs={Rs} heat=0

| | | | |
|---|---|---|---|
| L_Ld | drain | dd | {Ld} |

| | | | |
|---|---|---|---|
| *R_Ld | drain | dd | 10 |

| | | |
|---|---|---|
| L_Ls | source lsrs | {Ls} |

| | | |
|---|---|---|
| *R_Ls | source lsrs | 10 |

| | | | |
|---|---|---|---|
| R_Rs | s | lsrs | {Rs} |

| | | | |
|---|---|---|---|
| L_Lg | gate | lgrg | {Lg} |

| | | | |
|---|---|---|---|
| *R_Lg | gate | lgrg | 10 |

| | | | |
|---|---|---|---|
| R_Rg | lgrg | g | {Rg} |

| | | | |
|---|---|---|---|
| E1 | Tj | w | VALUE={TEMP} |
| R1 | w | 0 | 1u |

.ENDS
**********************************************************************

In the following, the formulas for the transistor core function, the non-linear resistor (JFET-like), the body diode and the nonlinear capacitances of the above model are described in more detail.

The core transistor functions model the static U/I transistor curves. In PSpice code, they include
Function 1:
.FUNC I0(Uee,p,pp,z1,cc) {if(Uee>pp,(Ue31 cc*z1)*z1,p*(pp−p)/cc*exp((Uee−pp)/p))}
Function 2:
.FUNC Ig(Uds,T,p,Uee,cc)
{bet*(T0/T)**nmu3*I0(Uee,p,min(2*p,p+cc*Uds),min(Uds,Uee/(2*cc)),cc)}
Function 3:
.FUNC J(d,g,T,da,s)+{a*(s*(Ig(da,T,(p0+(p1+p2*T)*T)*kbq*T,g−Vth+auth*(T−Tref),c)+1*exp(min(1B+(d−UB−ab*(T−Tref))/UT,25))))}
   Current Source (channel at Source of MOS):

G_chan d s VALUE={J(V(d,s),V(g,s),T0+limit(V(Tj),−200,499), (SQRT(1+4*al*abs(V(d,s)))−1)/2/al,sgn(V(d,s)))}

In mathematical notation, function 3 is given as

J=a·(s·I_{g}+e^{Exponent})

where
a is the transistor area
s=Ugs (Gate-Source-Voltage).

Function J (function 3) can be seen to not represent a physical MOS behavior but is only used as a fitting function. It calls function Ig (function 2).

In mathematical notation, function 2 is given as

$${I}_{g} = bet \cdot {( \frac{T 0}{T} )}^{nmu 3} \cdot {I}_{0}$$

where
bet is temperature coefficient 1
nmu3 is temperature coefficient 2
T is the simulation temperature
T0=273K (0° C.)
T=298K (ambient temperature, 25° C.)

Function J can be seen to not represent a physical MOS behavior but is only used as a fitting function. It calls function I0 (function 1).

In mathematical notation, function I0 is (depending on whether Uee>pp) either given by

I₀=(Uₑₑ−cc—z1)·z1

where

Uₑₑ=g−MOS_Vth0+MOS_Vth0_TC·(T−T_{ref})

is the effective threshold voltage
cc=MOS_C (fitting parameter)
T is the simulation temperature in K
and Tref is the reference temperature (298 K)
   or it is given by

$${I}_{0} = \frac{p \cdot ( pp - p )}{cc} \cdot {e}^{\frac{{U}_{ee} - pp}{p}}$$

where
p=MOS_p0·kbq·T
pp=2*p
   or
pp=p+MOS_c*Uds.

Function I0 can be seen to not represent a physical MOS behavior but is only used as a fitting function.

The non-linear resistor functions model the static U/I transistor curves and the nonlinearity of the drain drift zone. In PSpice code, they include
Voltage-controlled current source (channel at Drain of MOS):

G_G_Rd d2d1 VALUE{V(d2,d1)/(Rd0(T0+LIMIT(V(t1),−200,999))*CF(T0+LIMIT(V(t1),−200,999),abs(I(V_Iepi)))}
Function 4:
.FUNC Rd0(T) {(Rf*dRd+(1−Rf)*dRd*(T/Tref)**nmu)
Function 5:
.FUNC CF(T,Iepi){(Uc**2)/max(1,Uc**2−(Rd0(T)*Iepi)**limit(2+Uctemp*(T−Tre0,1.2,3))}

In mathematical formulation, the voltage-controlled current source formula is given by

$$G\_G {\_R}_{d} = \frac{V ( d 2 , d 1 )}{Rd 0 \cdot CF}$$

where V(d2,d1) is voltage over current source G_G_Rd.

Function 4 is given in mathematical formulation as

$$Rd 0 = MOS\_RF \cdot dRd + ( 1 - MOS\_RF ) \cdot dRd \cdot ( \frac{T}{{T}_{ref}} )$$

where
Rd0 is the temperature dependent drain resistor, fully integrated in JFET function part dRd is a resistance parameter
MOS_RF is a parameter (temperature coefficient)

Function Rd0 can be seen to not represent a physical MOS behavior but is only used as a fitting function.

Function 5 is given in mathematical formulation as

$$CF = \frac{{JFET\_UC}^{2}}{{JFET\_UC}^{2} - {( Rd 0 \cdot {I}_{epi} )}^{2 + JFET \_ UC \_ TC \cdot ( T - {T}_{ref} )}}$$

where
JFET_UC is a fitting parameter
JFET_UC_TC is a fitting parameter (temperature coefficient)
Iₑₚᵢ is the current of independent voltage source I(V_Iₑₚᵢ).

Function CF can be seen to not represent a physical MOS behavior but is only used as a fitting function. It calls function Rd0.

For the body diode, the model uses the SIMETRIX standard PSpice compact model. The compact model call is given by
.model dbody D (BV={UB*10}, CJO={Cdio}, TT={ta},
IS={a*exp(lnIsj)}m={1*0.3}RS={dRdi/100}N={ndi})

The current source is given in Pspice code by
G_Rdio dio2 dd VALUE={V(dio2,dd)/(dRdi*((limit(V(Tj),−200,999)+T0)/Tref)**nmu2)}

The components of the capacitance network 500 model the nonlinear voltage-dependent capacitances based on using voltage-controlled voltage sources. In Pspice code, it includes the fitting functions
Function 6:
.FUNC QCdg1(x){Cdg2*min(x,x1)+CdgV2*max(x−x1,0)+CdgV1/2*max(0,x−pc22)**2+(Cdg2−CdgV2)*((limit(x,x0,x1)x0)**3/(dx*dx)*((limit(x,x0,x1)−x0)/(2*dx)−1))}
Function 7:
.FUNC QCds1(x){CdS1*min(x,a1)+Cds1*((limit(x,a0,a1)−a0)**3/(da*da)*((limit(x,a0,a1)−a0)/(2*da)−1))}

In mathematical notation, function 6 is given by

$$QCdg 1 ( x ) = Cdg 2 \cdot x + CdgV 2 \cdot x + \frac{CdgV 1}{2} \cdot {( x - pc 22 )}^{2} + ( Cdg 2 - CdgV 2 ) \cdot \frac{{( x - x 0 )}^{3}}{{dx}^{2}} \cdot \frac{x - x 0}{( 2 dx - 1 )}$$

where
Cdg2 is a fitting parameter
CdgV1, CdgV2 are fitting parameters
pc22 is a fitting parameter
x, x0, dx are auxiliary parameters.

Function QCdg1 can be seen to not represent a physical MOS behavior but is only used as a fitting function.

Function 7 is given in mathematical notation by

$$QCds 1 ( x ) = Cds 1 \cdot x + Cds 1 \cdot \frac{{( x - a 0 )}^{3}}{{da}^{2}} \cdot \frac{x - a 0}{( 2 da - 1 )}$$

where
CdS1 is a fitting parameter
x, a0, da are auxiliary parameters.

Function QCdS1 can be seen to not represent a physical MOS behavior but is only used as a fitting function.

In the following, the effect of some of the parameters used in the model described above is illustrated.

Regarding the nonlinearity of the drain current JFET similar functionality in the drift zone, the main parameter for setting the nonlinear resistor function may be seen as Uc (or JFET_UC), see function 5 above.

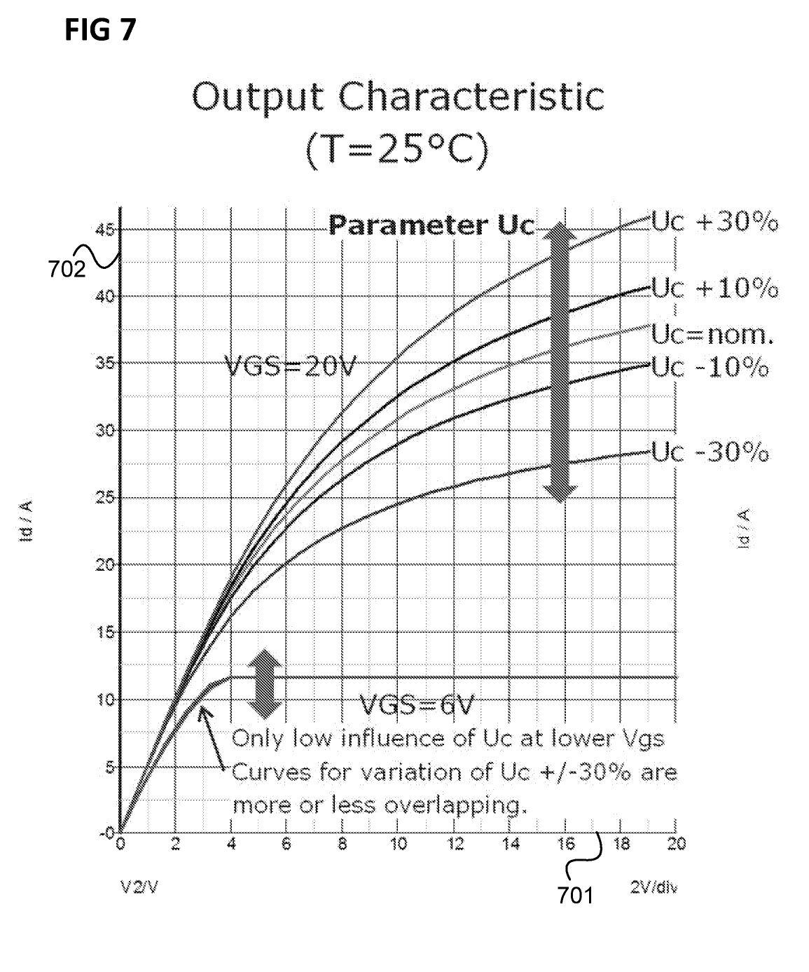

FIG. 7 shows the output characteristic in dependence of the parameter Uc.

The drain source voltage increases from left to right along the horizontal axis 701 and the drain current increases from bottom to top along the vertical axis 702.

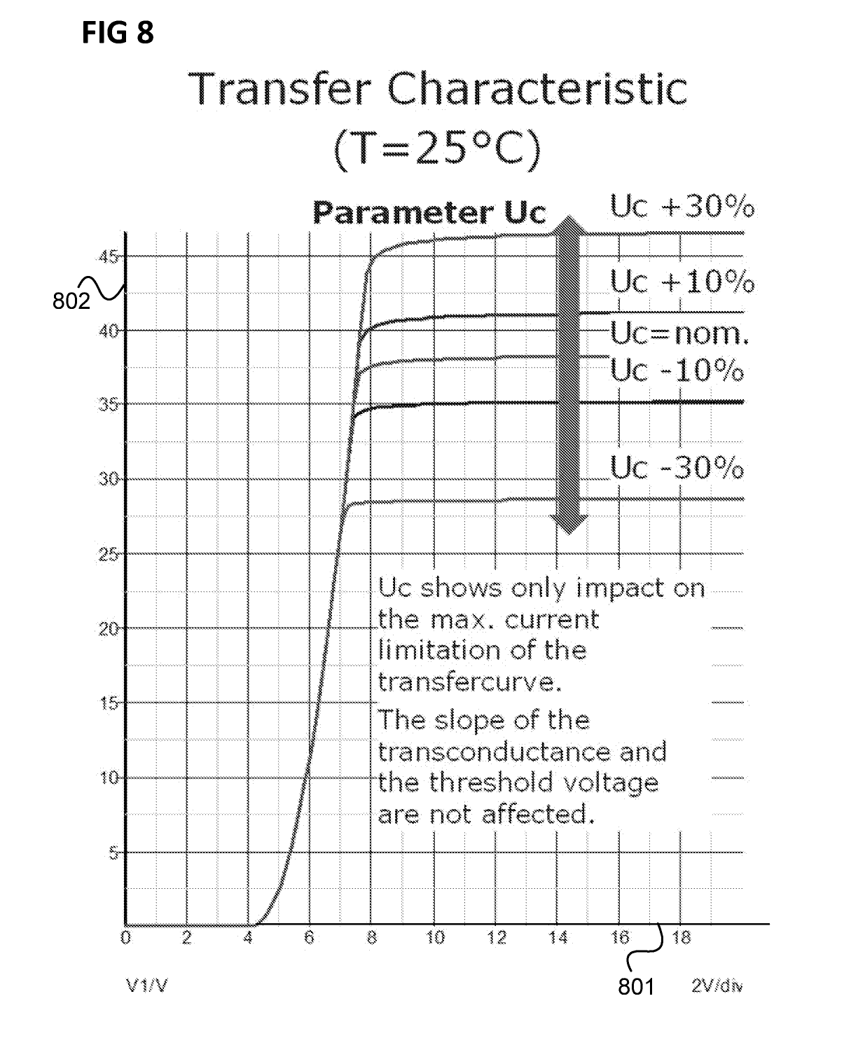

FIG. 8 shows the transfer characteristic in dependence of the parameter Uc.

The gate source voltage increases from left to right along the horizontal axis 801 and the drain current increases from bottom to top along the vertical axis 802.

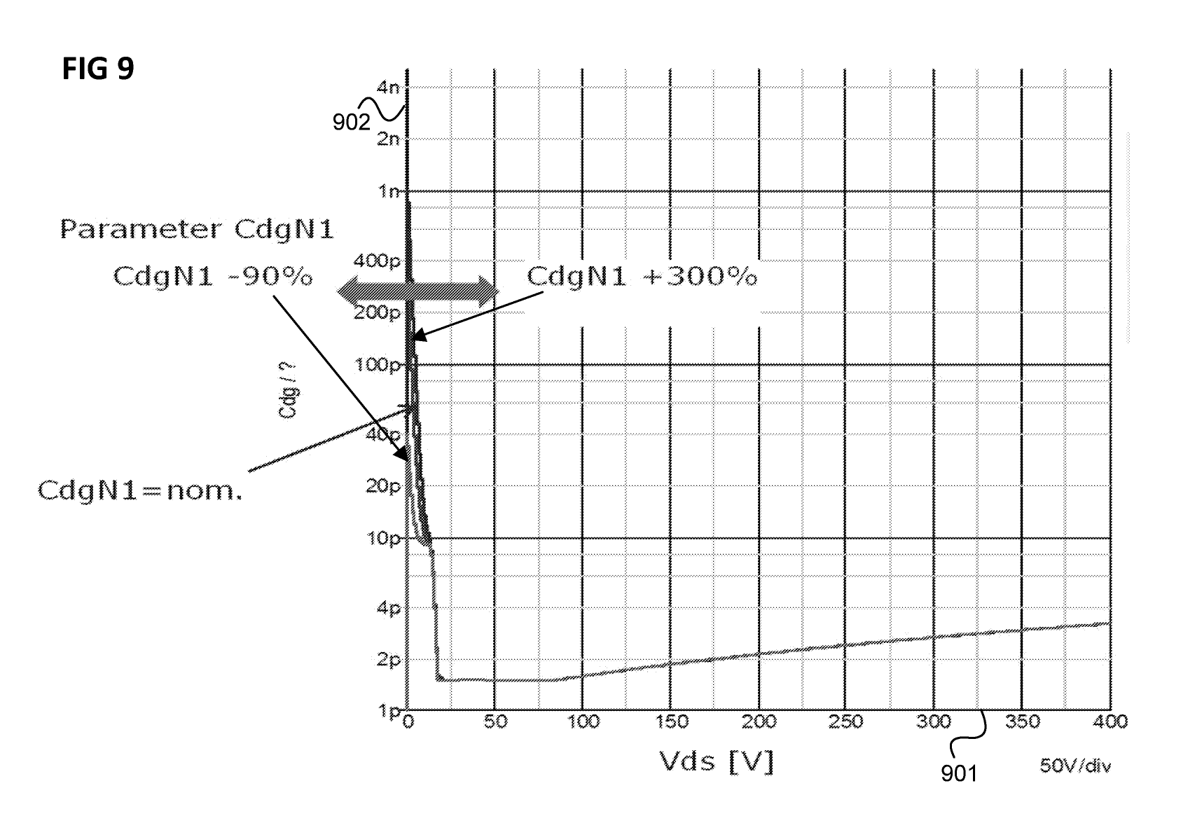

FIG. 9 illustrates the nonlinearity of the drain-gate capacitance in dependence on the parameter CdgN1.

The drain source voltage increases from left to right along the horizontal axis 901 and the drain-gate capacitance increases from bottom to top along the vertical axis 902.

CdgN1 is a parameter that influences the drain-gate capacitance at a very low voltage range for Vds. It controls the source E_Edg1 which is valid up to the sharp bend in the curve characterisitic.

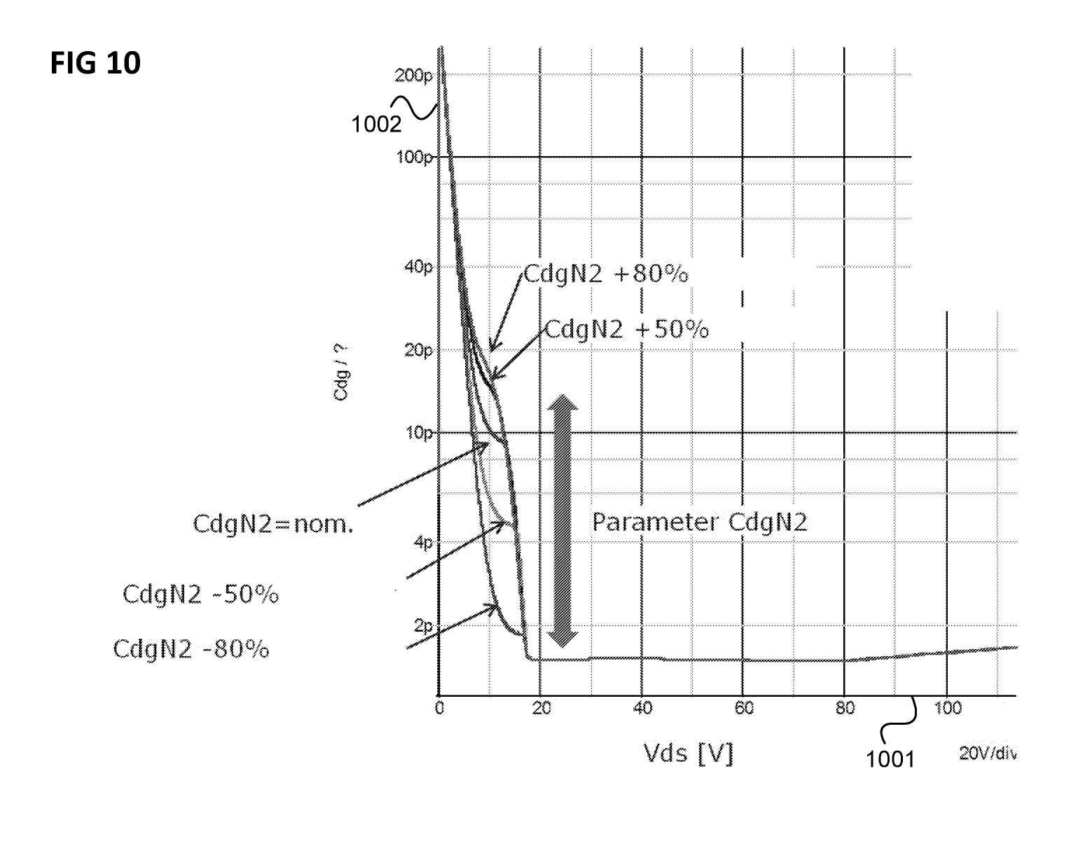

FIG. 10 illustrates the nonlinearity of the drain-gate capacitance in dependence on the parameter CdgN2.

The drain source voltage increases from left to right along the horizontal axis 1001 and the drain-gate capacitance increases from bottom to top along the vertical axis 1002.

CdgN2 models the position of the sharp bend in the curve characteristic.

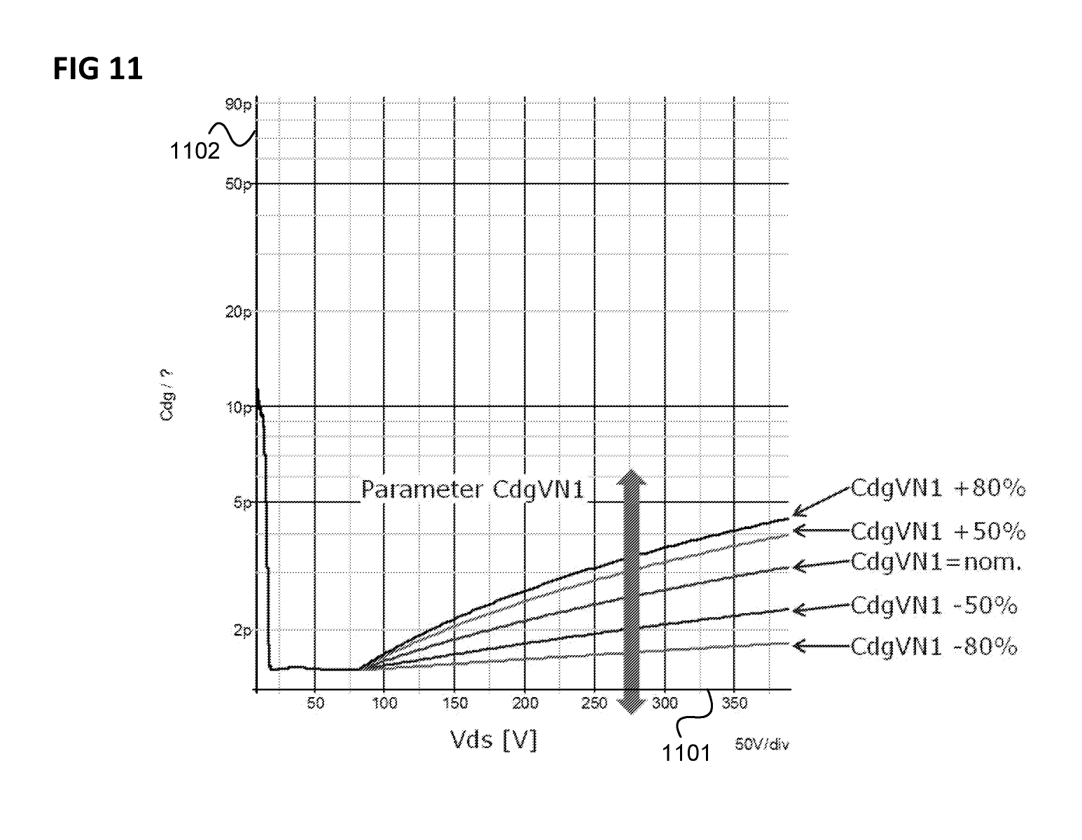

FIG. 11 illustrates the nonlinearity of the drain-gate capacitance in dependence on the parameter CdgVN1.

The drain source voltage increases from left to right along the horizontal axis 1101 and the drain-gate capacitance increases from bottom to top along the vertical axis 1102.

CdgVN1 models the rise of the capacitance at higher voltages. It shows no impact on the capacitance at lower Vds. The source E_Edg2 is controlled by this parameter.

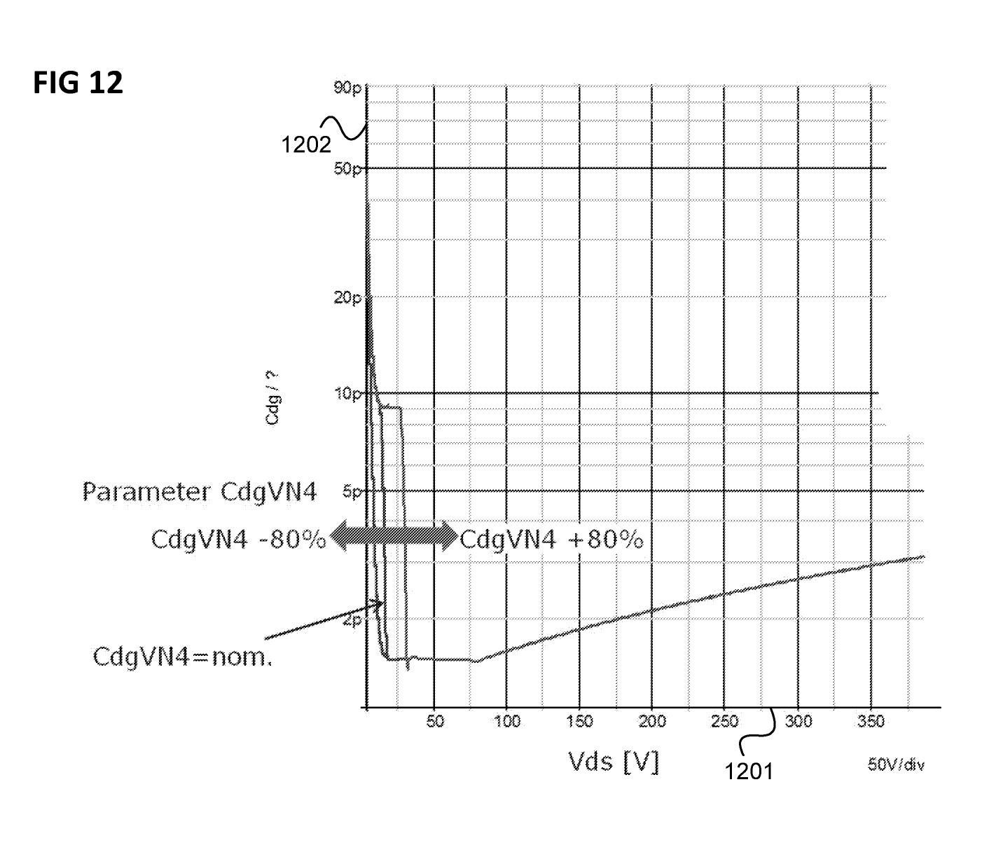

FIG. 12 illustrates the nonlinearity of the drain-gate capacitance in dependence on the parameter CdgVN4.

The drain source voltage increases from left to right along the horizontal axis 1201 and the drain-gate capacitance increases from bottom to top along the vertical axis 1202.

CdgVN4 models the vertical position of the step in the Cdg function. I has no impact on Cdg at higher voltages.

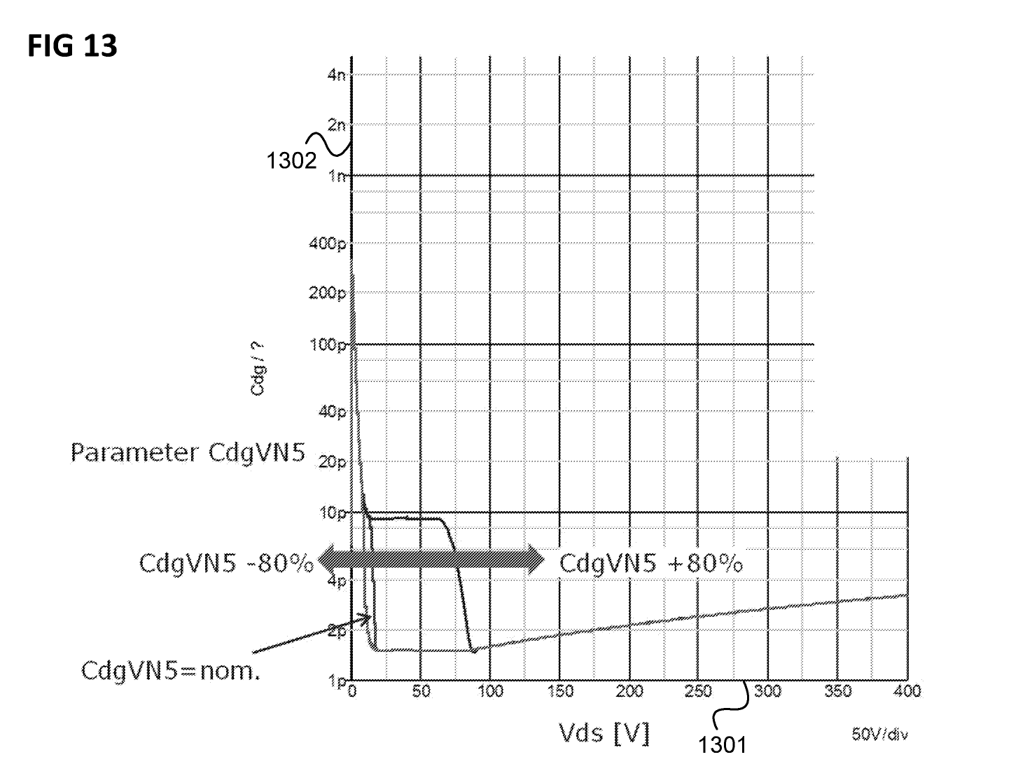

FIG. 13 illustrates the nonlinearity of the drain-gate capacitance in dependence on the parameter CdgVN5.

The drain source voltage increases from left to right along the horizontal axis 1301 and the drain-gate capacitance increases from bottom to top along the vertical axis 1302.

CdgVN5 models the vertical position of the step in the Cdg function. Compared to CdgVN4 the impact here is much stronger. It is an additional parameter to adjust the bend in the curve's shape.

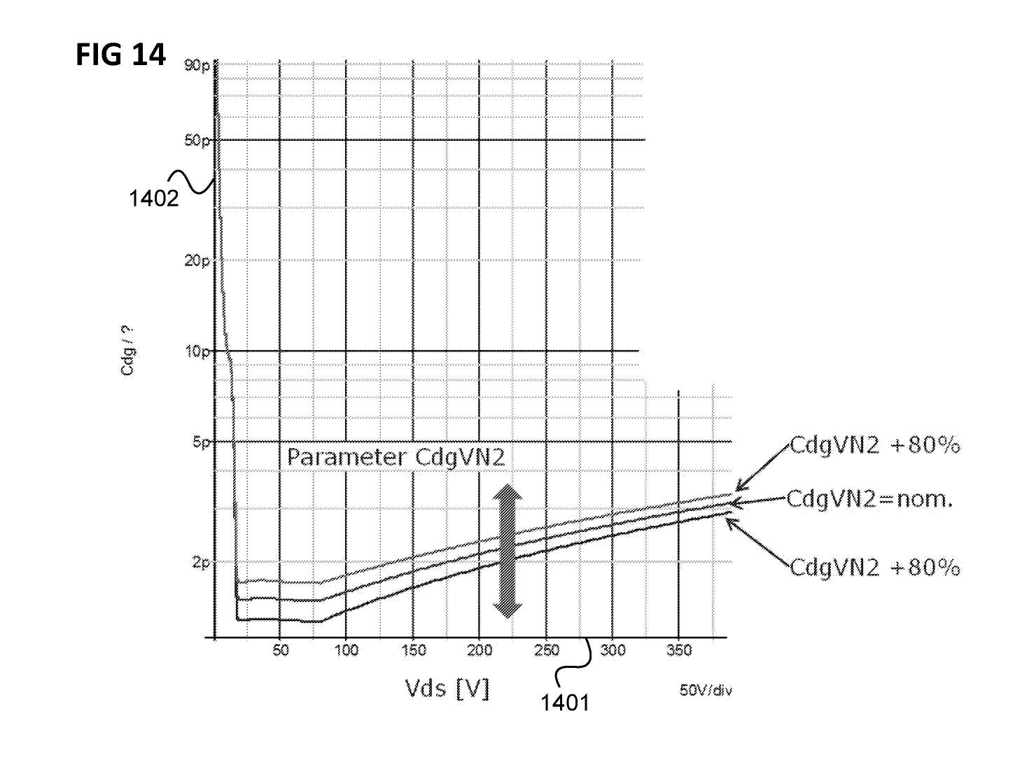

FIG. 14 illustrates the nonlinearity of the drain-gate capacitance in dependence on the parameter CdgVN2.

The drain source voltage increases from left to right along the horizontal axis 1401 and the drain-gate capacitance increases from bottom to top along the vertical axis 1402.

CdgVN2 is modelling the capcitance Cdg after the first sharp step in the characteristic. This parameter is scaling directly with the area parameter a. In addition, the parameter CdgVN3 is defined which is representing the contribution of the edge capacitance. Its impact is not shown since it is identical to CdgVN2.

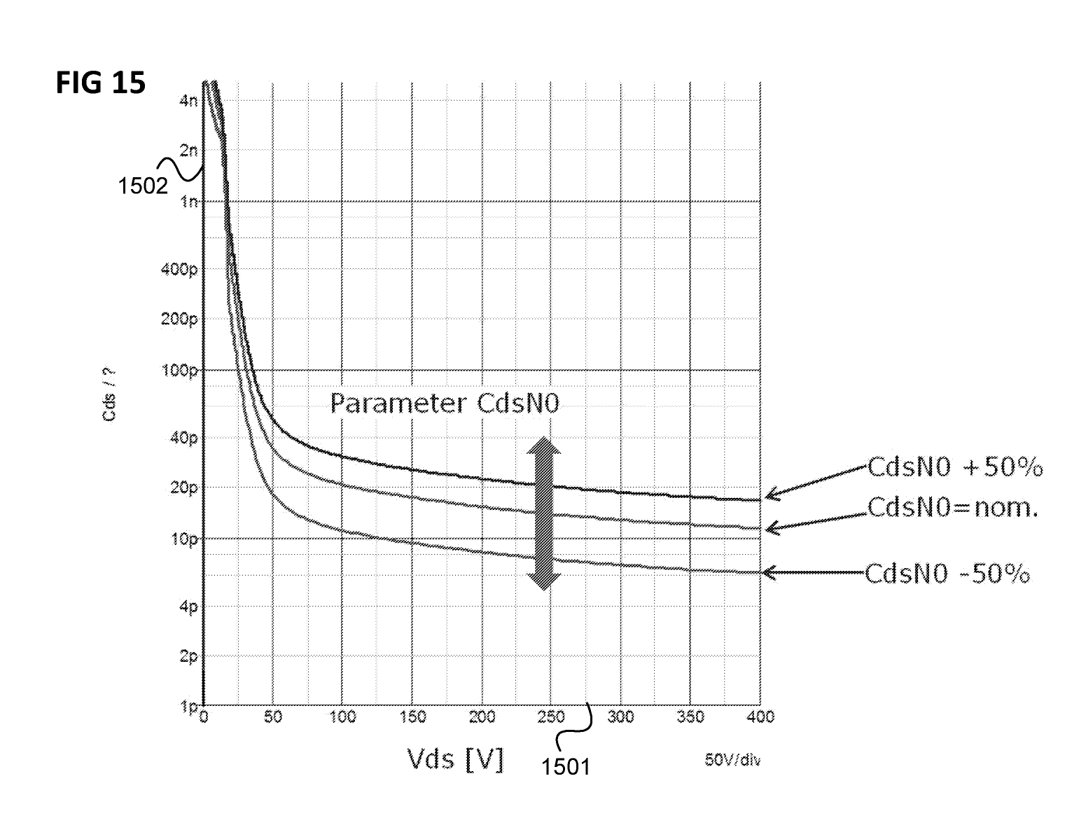

FIG. 15 illustrates the nonlinearity of the drain-source capacitance in dependence on the parameter CdsN0.

The drain source voltage increases from left to right along the horizontal axis 1501 and the drain-source capacitance increases from bottom to top along the vertical axis 1502.

CdsN0 influences Cds like an offset value over the whole voltage range. The maximum Cds at high voltages can be adjusted. It is scaling directly with the area parameter a.

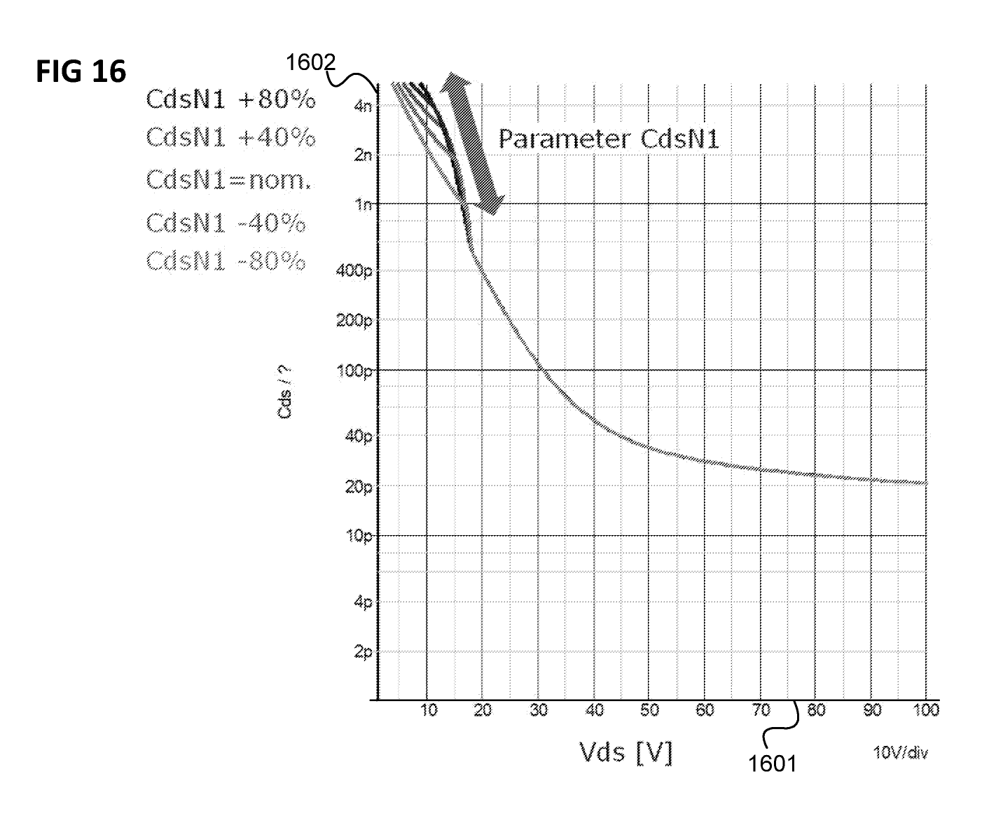

FIG. 16 illustrates the nonlinearity of the drain-source capacitance in dependence on the parameter CdsN1.

The drain source voltage increases from left to right along the horizontal axis 1601 and the drain-source capacitance increases from bottom to top along the vertical axis 1602.

CdsN1 models the position of the bend at lower voltages. It can be adjusted to a certain capacitance level. This parameter controls the source E_Eds2. It shows no influence on Cds at higher voltage ranges.

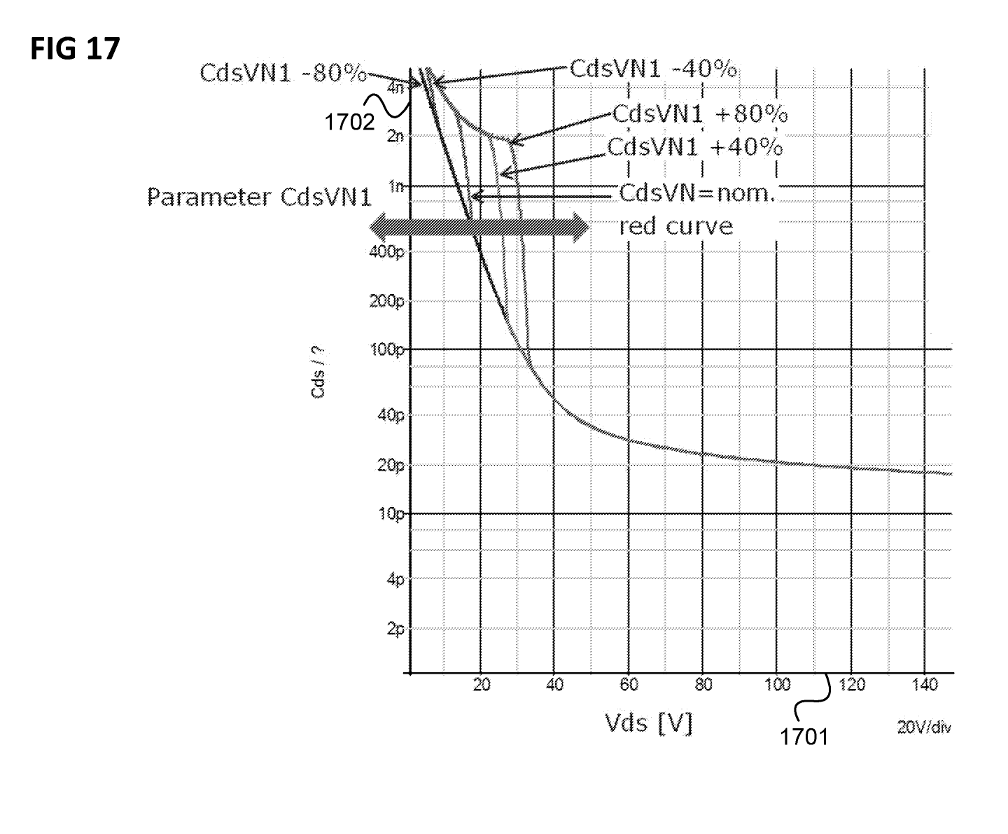

FIG. 17 illustrates the nonlinearity of the drain-source capacitance in dependence on the parameter CdsVN1.

The drain source voltage increases from left to right along the horizontal axis 1701 and the drain-source capacitance increases from bottom to top along the vertical axis 1702.

CdsVN1 models the position of the bend. It can be adjusted to a certain voltage level. The parameter shows no influence on Cds at higher voltage ranges.

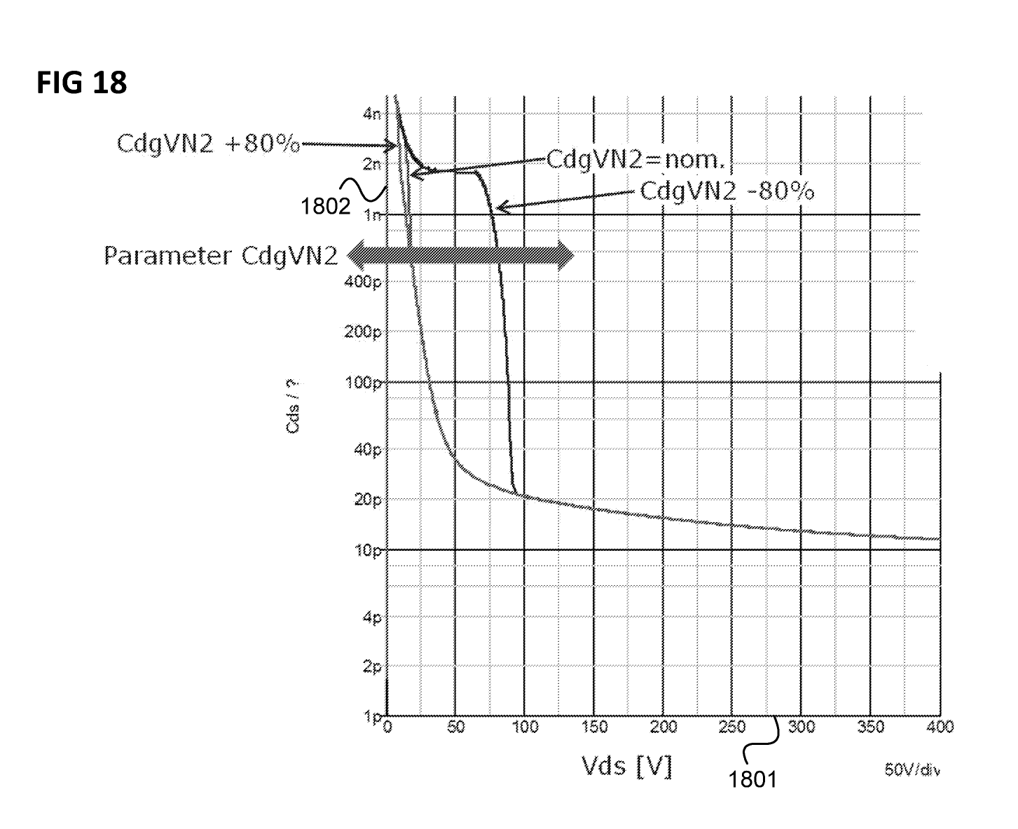

FIG. 18 illustrates the nonlinearity of the drain-source capacitance in dependence on the parameter CdsVN2.

The drain source voltage increases from left to right along the horizontal axis 1801 and the drain-source capacitance increases from bottom to top along the vertical axis 1802.

CdsVN2 models the position of the bend similar to CdsVN1 but with much stronger impact. The parameter shows no influence on Cds at higher voltage ranges.

A comparison of measurements and simulation by means of the transistor model described above shows that a high model accuracy can be achieved, e.g. in comparison with compact models. This allows using the model under system conditions.

While specific aspects have been described, it should be understood by those skilled in the art that various changes in form and detail may be made therein without departing from the spirit and scope of the aspects of this disclosure as defined by the appended claims The scope is thus indicated by the appended claims and all changes which come within the meaning and range of equivalency of the claims are therefore intended to be embraced.

What is claimed is:

1. A power transistor model comprising:
a source drain path;
a first current source and a voltage controlled second current source in the source drain path which model the static voltage-current-relationship of a modeled power transistor;
wherein the voltage-controlled second current source models a nonlinear behavior of a drift zone of the power transistor.

2. The power transistor model of claim 1, wherein the voltage-controlled second current source models a JFET effect.

3. The power transistor model of claim 1, wherein the second current source is voltage-controlled by the voltage over the second current source.

4. The power transistor model of claim 1, wherein the second current source has the behavior of a non-linear resistor.

5. The power transistor model of claim 1, wherein the second current source is connected in series to the first current source.

6. The power transistor model of claim 1, wherein the first current source gives a channel current depending on the drain source voltage and depending on the gate source voltage of the power transistor.

7. The power transistor model of claim 1, wherein the first current source gives a channel current depending on the size of the active area of the power transistor.

8. The power transistor model of claim 1, further including a body diode model arranged in a path which is parallel to the part of the source drain path which comprises the first current source.

9. The power transistor model of claim 8, wherein the path is serial to the part of the source drain path which comprises the second current source.

10. A power transistor model comprising:
a gate terminal, a source terminal and a drain terminal and
a capacitance network comprising one or more nonlinear voltage dependent capacitances, wherein each nonlinear voltage dependent capacitance is connected between the drain terminal and the source terminal or the drain terminal and the gate terminal.

11. The power transistor model of claim 10, wherein the capacitance network further comprises a capacitance connected between the drain terminal and the source terminal.

12. The power transistor model of claim 11, wherein the capacitance connected between the drain terminal and the source terminal is a voltage independent capacitance.

13. The power transistor model of claim 10, wherein the capacitance network further comprises a capacitance connected between the gate terminal and the source terminal.

14. The power transistor model of claim 13, wherein the capacitance connected between the gate terminal and the source terminal is a voltage independent capacitance.

15. The power transistor model of claim 10, wherein each nonlinear voltage dependent capacitance is modeled by means of a voltage-controlled voltage source.

16. The power transistor model of claim 10, wherein each nonlinear voltage dependent capacitance is modeled by means of a serial connection of a voltage-controlled voltage source and a voltage-independent capacitance.

17. The power transistor model of claim 10, wherein the capacitance network comprises one or more nonlinear voltage dependent capacitances connected between the drain terminal and the source terminal and comprises one or more nonlinear voltage dependent capacitances connected between the drain terminal and the gate terminal.

18. A method for simulating the behavior of an electronic circuit comprising a power transistor using a power transistor model according to claim 1.

19. A method for simulating the behavior of an electronic circuit comprising a power transistor using a power transistor model according to claim 10.
